(19) United States
(12) Patent Application Publication
(10) Pub. No.: US 2009/0142917 A1
(43) Pub. Date: Jun. 4, 2009

(54) METHOD FOR FABRICATING METAL LINE OF SEMICONDUCTOR DEVICE

(75) Inventor: Joon Hwan KIM, Seongnam-si (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/261,975

(22) Filed: Oct. 30, 2008

(30) Foreign Application Priority Data
Nov. 29, 2007 (KR) 10-2007-0122588

(51) Int. Cl. H01L 21/4763

(52) U.S. Cl. 438/626; 257/E21.495

(57) ABSTRACT

Methods for fabricating a metal line of a semiconductor device are disclosed. In a disclosed example, the method includes a first step of forming a passivation film on a semiconductor substrate having a semiconductor device, a second step of forming contact holes in the passivation film to form a first contact plug, a third step of sequentially forming at least two metal layers on an entire surface of the substrate including the first contact plug, a fourth step of selectively etching one of the at least two metal layers to form a second contact plug, a fifth step of selectively etching the other of the at least two metal layers to form a metal line, and a sixth step of exposing an upper surface of the second contact plug.

### CROSS-REFERENCE TO RELATED APPLICATION

This application claims priority to Korean Application No. 10-2007-0122588, filed on Nov. 29, 2007, which is incorporated herein by reference in its entirety.

### BACKGROUND

1. The Field of the Invention

Embodiments of the present invention relate to semiconductor devices. More particularly, embodiments of the present invention relate to methods for fabricating a metal line of a semiconductor device.

2. Description of Related Art

Semiconductor devices typically include components such as transistors, bit lines, capacitors and the like. As semiconductor devices are further miniaturized, a process is often required to form a multilayer interconnection, such as metal lines, to electrically interconnect such components within the semiconductor device.

To provide such metal interconnect lines, a passivation film is typically formed on the entire surface of a semiconductor substrate, including a device layer having components such as a transistor, a bit line and a capacitor. The passivation film is can then be planarized by a chemical mechanical polishing (CMP) process, and contact holes are formed in the device layer to form a contact plug in the contact holes.

A first interlayer insulating film is then formed on the passivation film and is also typically planarized by a CMP process. Then, a first metal line is formed on the first interlayer insulating film. Subsequently, a second interlayer insulating film is formed on the first interlayer insulating film including the first metal line. Contact holes are then formed above the first metal line and a contact plug is formed in the contact holes. Then, a second metal line is formed on the second interlayer insulating film. The above process is repeated to form a multilayer metal interconnection.

One conventional method for fabricating a metal line of a semiconductor device will be described with reference to the accompanying drawings.

FIGS. 1A to 1E illustrate cross-sectional views of the steps of a conventional method for fabricating a metal line of a semiconductor device.

First, as shown in FIG. 1A, a semiconductor device such as a photodiode, a transistor or a capacitor is formed on a semiconductor substrate 1. FIG. 1A illustrates a MOS transistor, serving as a semiconductor device, including a gate terminal G and source/drain terminals S and D. A passivation film 2 is deposited on the entire surface of the semiconductor substrate 1.

As shown in FIG. 1B, the passivation film 2 is selectively removed using a photolithography process, so as to form first contact holes 3 in the passivation film 2 to expose the gate terminal G or/and the source/drain terminals S and D of the semiconductor device. Next, a metal layer (e.g., tungsten) is deposited on the passivation film 2 and in the first contact holes 3. Then, a chemical mechanical polishing (CMP) process is performed to form a first contact plug 4 made of a metal layer in the first contact holes 3.

Referring next to FIG. 1C, a metal material for forming a metal line is then deposited on the passivation film 2 and is patterned to form a first metal line 5 electrically connected to the first contact plug 4. Then, an undoped silicate glass (USG) oxide film or the like is deposited on the entire surface of the semiconductor substrate 1 including the first metal line 5 to form a first interlayer insulating film 6.

In this case, the surface of the first interlayer insulating film 6 may be bent unevenly due to a height difference of the first metal line 5 under the first interlayer insulating film 6. The CMP process may be performed to planarize the first interlayer insulating film 6.

As shown in FIG. 1D, the first interlayer insulating film 6 is selectively removed using a photolithography process to form second contact holes 7 on the first metal line 5. After a metal layer (tungsten) is deposited on the first interlayer insulating film 6 having the second contact holes 7 such that the second contact holes 7 are filled, the CMP process is performed to form a second contact plug 8 in the second contact holes 7.

As shown in FIG. 1E, a metal material for forming a metal line is deposited on the first interlayer insulating film 6 and is patterned to form a second metal line 9 to be electrically connected to the second contact plug 8.

The metal lines and the contact plugs are formed by repeating the above process to form a multilayer metal interconnection structure.

However, the conventional method for fabricating a metal line of a semiconductor device has the following problems.

For example, when the multilayer metal interconnection of the semiconductor device is formed using this type of method, the interlayer insulating film is deposited on the lower metal line and the interlayer insulating film is selectively removed to form the contact holes. Then, the contact plug is formed in the contact holes and the upper metal line is formed thereon. If there are foreign substances, such as particles on the interlayer insulating film adjacent to the contact holes, the resulting contact holes may only partially expose the lower metal line. If the contact holes are not completely formed, the metal line is exposed and may render the semiconductor device defective, or reduce the operation speed of the device due to an increase in contact resistance.

### SUMMARY OF SOME EXAMPLE EMBODIMENTS

Accordingly, embodiments of the present invention are directed to methods for fabricating a metal line of a semiconductor device that addresses problems presented by prior art solutions. For example, disclosed methods for fabricating a metal line of a semiconductor device substantially reduce contact defects, reduce the resistance of the metal line and improve the operational speed of the semiconductor device.

In one disclosed embodiment, a method for fabricating a metal line of a semiconductor device comprises: a first step of forming a passivation film on a semiconductor substrate having a semiconductor device; a second step of forming contact holes in the passivation film to form a first contact plug in the contact holes; a third step of sequentially forming at least two metal layers on an entire surface of the substrate including the first contact plug; a fourth step of selectively etching one of the at least two metal layers to form a second contact plug; a fifth step of selectively etching the other of the at least two metal layers to form a metal line; and a sixth step of forming an interlayer insulating film on the second contact plug and the metal line to expose an upper surface of the second contact plug.

Using this approach, instead of electrically connecting the metal lines by forming the contact holes, after metal layers for a metal line and a contact plug are deposited, the metal layers for a metal line and a contact plug are selectively etched two times to form the metal line and the contact plug as a single body. Accordingly, it is possible to prevent contact defects between the metal lines and minimize the contact resistance between the metal lines and the contact plug. This improves the operational speed of the semiconductor device.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

Additional features will be set forth in the description which follows, and in part will be obvious from the description, or may be learned by the practice of the teachings herein. Features of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

To further clarify the above and other advantages and features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIGS. 1A to 1E illustrate cross-sectional views of the steps of a conventional method for fabricating a metal line of a semiconductor device; and

FIGS. 2A to 2E illustrate cross-sectional views showing the steps of a method for fabricating a metal line of a semiconductor device according to the embodiment of the present invention.

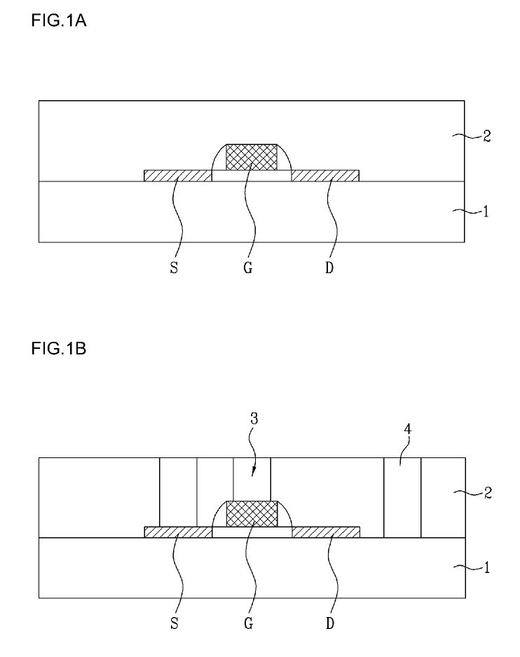

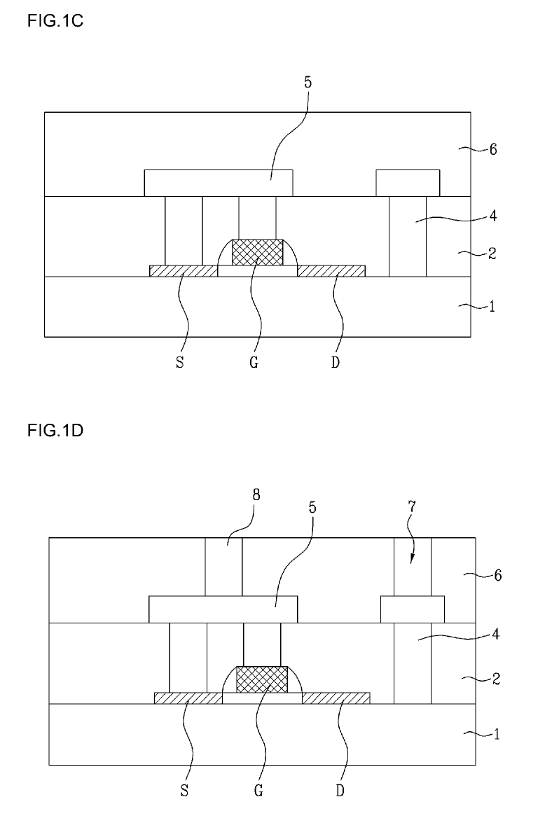

### DETAILED DESCRIPTION OF SOME EXAMPLE EMBODIMENTS

In the following detailed description of the embodiments, reference is made to the accompanying drawings that show, by way of illustration, specific embodiments of the invention. In the drawings, like numerals describe substantially similar components throughout the several views. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

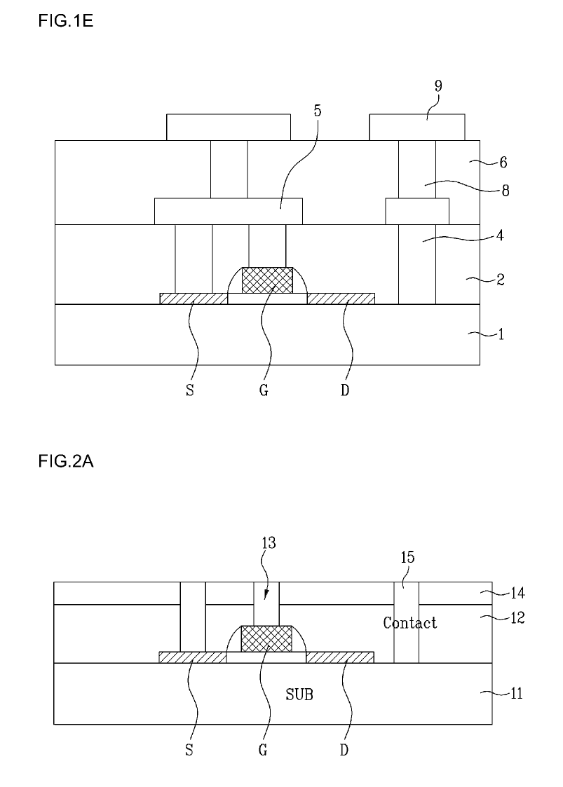

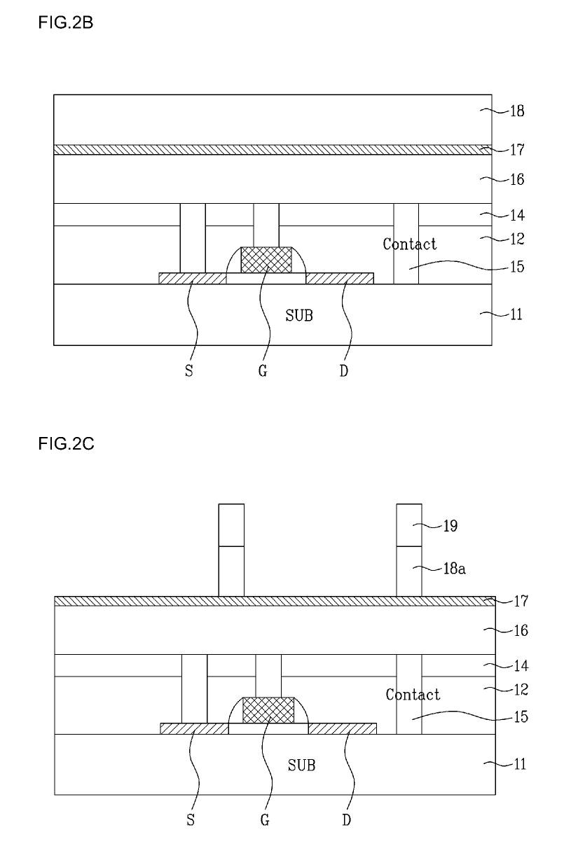

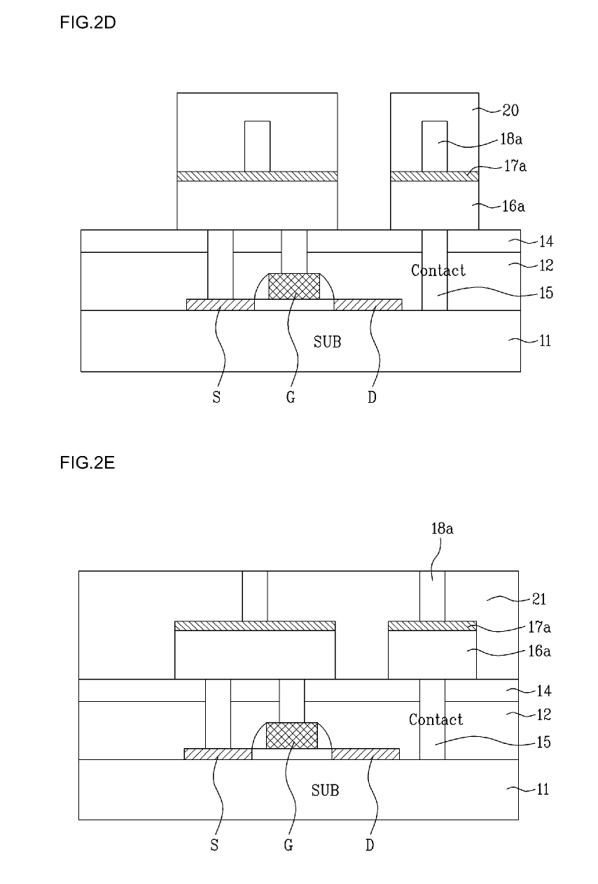

FIGS. 2A to 2E illustrate cross-sectional views showing the steps of one example embodiment of a method for fabricating a metal line of a semiconductor device.

Referring first to FIG. 2A, a semiconductor device such as a photodiode, a transistor or a capacitor is formed on a semiconductor substrate 11. For example, a MOS transistor including a gate terminal G and source/drain terminals S and D is illustrated in the drawings.

A passivation film 12 and a first interlayer insulating film 14 such as an undoped silicate glass (USG) oxide film are sequentially deposited on the substrate 11. The first interlayer insulating film 14 and the passivation film 12 are then selectively removed using a photolithography process so as to form contact hole(s) 13 in the first interlayer insulating film 14 and the passivation film 12. The contact hole(s) are formed so as to expose the gate terminal G and/or the source/drain terminals S and D of the semiconductor device.

A metal layer (e.g., tungsten) is then deposited on the first interlayer insulating film 14 and the contact holes 13 are filled. A chemical mechanical polishing (CMP) process is next performed to form a first contact plug 15 in the contact holes 3. The first contact plug 15 may be formed of a single metal layer, or may have a double structure formed by stacking a barrier metal layer and a metal layer.

Referring next to FIG. 2B, a first metal layer 16, a second metal layer 17 and a third metal layer 18 are then sequentially formed on the entire surface of the first interlayer insulating film 14, including the first contact plug 15.

In the example embodiment, the first and third metal layers 16 and 18 are formed of aluminum, an aluminum alloy, copper, a copper alloy, a copper-aluminum alloy or the like. The second metal layer 17 is formed of titanium, titanium nitride or an alloy thereof The first metal layer 16 serves as a first metal line and the second metal layer 17 serves as an etch stopper. The third metal layer 18 is utilized to form a second contact plug. Accordingly, the thickness of the first to second metal layers may be determined with regard to the thickness of the metal line and the depth of the second contact plug.

Referring next to FIG. 2C, a first photoresist film is then deposited on the entire surface of the third metal layer 18, and the first photoresist film is patterned through exposure and development to remain only at a portion for forming a second contact plug, thereby forming a first photoresist film pattern 19.

Next, the third metal layer 18 is selectively etched using the first photoresist film pattern 19 as a mask to expose the surface of the second metal layer 17, thereby forming a second contact plug 18a. That is, the second metal layer 17 serves as an etch stopper when the third metal layer 18 is etched.

As shown in FIG. 2D, the first photoresist film pattern 19 is removed, and a second photoresist film is deposited on the entire surface of the semiconductor substrate. The second photoresist film is patterned through exposure and development to remain only at a portion for forming a first metal line, thereby forming a second photoresist film pattern 20.

Then, the second metal layer 17 and the first metal layer 16 are selectively removed using the second photoresist film pattern 20 as a mask to form a first metal line 16a and 17a.

As shown in FIG. 2E, after the second photoresist film pattern 20 is removed, a second interlayer insulating film 21 is deposited on the entire surface of the semiconductor substrate 11 to completely cover the first metal line 16a and 17a and the second contact plug 18a.

Next, the second interlayer insulating film 21 is planarized by, for example, a CMP process to expose the surface of the second contact plug 18a.

Further, although not shown in the drawings, the metal line and the contact plug are formed by repeating the steps shown in FIGS. 2B to 2E, thereby forming the multilayer metal interconnection.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method for fabricating a metal line of a semiconductor device, comprising:
a first step of forming a passivation film on a semiconductor substrate having a semiconductor device;
a second step of forming a contact hole in the passivation film to form a first contact plug;
a third step of sequentially forming at least two metal layers on a surface of the substrate including the first contact plug;
a fourth step of selectively etching one of the at least two metal layers to form a second contact plug;
a fifth step of selectively etching the other of the at least two metal layers to form a metal line; and
a sixth step of exposing a surface of the second contact plug.

2. The method according to claim 1, wherein a multilayer metal interconnection is formed by repeating the third to sixth steps.

3. The method according to claim 1, wherein the first contact plug is a single metal layer.

4. The method according to claim 1, wherein the first contact plug has a double structure formed by stacking a barrier metal layer and a metal layer.

5. The method according to claim 1, wherein the third step includes sequentially forming a first metal layer, a second metal layer and a third metal layer.

6. The method according to claim 5, wherein the first and third metal layers are formed of aluminum, an aluminum alloy, copper, a copper alloy, a copper-aluminum alloy or the like, and the second metal layer is formed of titanium, titanium nitride or an alloy thereof

7. The method according to claim 5, wherein the fourth step includes selectively etching the third metal layer to form the second contact plug.

8. The method according to claim 5, wherein the fifth step includes selectively removing the second metal layer and the first metal layer to form a first metal line.

9. The method according to claim 7, wherein the fourth step includes:
depositing a first photoresist film on an entire surface of the third metal layer;
patterning the first photoresist film through exposure and development such that the first photoresist film remains only at a portion for forming the second contact plug to form a first photoresist film pattern;
selectively etching the third metal layer using the first photoresist film pattern as a mask to expose a surface of the second metal layer to form the second contact plug; and
removing the first photoresist film pattern.

10. The method according to claim 9, wherein the second metal layer serves as an etch stopper when the third metal layer is etched.

11. The method according to claim 9, wherein the fifth step includes:
depositing a second photoresist film on an entire surface of the semiconductor substrate;
patterning the second photoresist film through exposure and development such that the second photoresist film remains only at a portion for forming a first metal line to form a second photoresist film pattern;
selectively removing the second metal layer and the first metal layer using the second photoresist film pattern as a mask to form the first metal line; and
removing the second photoresist film pattern.

12. The method according to claim 1, wherein the sixth step includes:
depositing an interlayer insulating film on the entire surface of the semiconductor substrate to completely cover the metal line and the second contact plug; and
planarizing the interlayer insulating film to expose the surface of the second contact plug.

13. The method according to claim 12, wherein the planarizing step is performed with a chemical mechanical polishing (CMP) process.
